(19) United States
(12) Patent Application Publication
(10) Pub. No.: US 2025/0096175 A1
(43) Pub. Date: Mar. 20, 2025

(54) SEMICONDUCTOR PACKAGE AND METHOD FOR MANUFACTURING THE SAME

(71) Applicant: SAMSUNG ELECTRONICS CO., LTD., Suwon-si (KR)

(72) Inventors: YISEUL HAN, Suwon-si (KR); KWANG-SOO KIM, Suwon-si (KR); JAESUN KIM, Suwon-si (KR)

(73) Assignee: SAMSUNG ELECTRONICS CO., LTD., Suwon-si (KR)

(21) Appl. No.: 18/794,640

(22) Filed: Aug. 5, 2024

(30) Foreign Application Priority Data
Sep. 15, 2023 (KR) 10-2023-0123331

(51) Int. Cl. H01L 23/00; H01L 21/48; H01L 21/56; H01L 23/367; H01L 23/373; H01L 23/498; H01L 25/065; H01L 25/18; H10B 80/00

(52) U.S. Cl. CPC H01L 24/16; H01L 21/4857; H01L 21/568; H01L 23/3677; H01L 23/3736; H01L 23/49833; H01L 23/49838; H01L 23/49866; H01L 25/0655; H01L 25/18; H01L 2224/16225; H01L 2924/1431; H01L 2924/1436; H01L 2924/1437; H01L 2924/19041; H01L 2924/19105; H10B 80/00

(57) ABSTRACT

A semiconductor package includes a first redistribution layer structure, a first set of semiconductor dies on the first redistribution layer structure, a plurality of connection members on the first redistribution layer structure and around the first set of semiconductor dies, a molding material on the first redistribution layer structure, the molding material covering the first set of semiconductor dies and at least partially surrounding the plurality of connection members, a second redistribution layer structure on the molding material, a second set of semiconductor dies on the second redistribution layer structure, and a dummy structure on the second redistribution layer structure and between a first semiconductor die of the second set of semiconductor dies and a second semiconductor die of the second set of semiconductor dies.

### CROSS-REFERENCE TO RELATED APPLICATION

This application is based on and claims priority to Korean Patent Application No. 10-2023-0123331, filed on Sep. 15, 2023, in the Korean Intellectual Property Office, the disclosure of which is incorporated herein by reference in its entirety.

### BACKGROUND

Example embodiments of the disclosure relate to a semiconductor package and a method for manufacturing the same.

The semiconductor industry is seeking to improve integration density such that more passive or active devices may be integrated within a given region. Therefore, the need for packaging technology that provides high integration density is increasing, such as packaging technology of a multi-chip fan-out wafer-level package (FOWLP) having a shape in which semiconductor chips may be mounted and package input/output (I/O) terminals are disposed outside the semiconductor chip.

In related art multi-chip fan-out wafer level packages, conductive posts may be between the semiconductor chips of the lower structure, causing the horizontal size of the semiconductor package to increase. In addition, because a space between the semiconductor chips of an upper structure is filled only with a molding material and no other structures are disposed, in a bending evaluation, the strength may be low.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a multi-chip fan-out wafer level package with improved the strength.

Additional aspects will be set forth in part in the description which follows and, in part, will be apparent from the description, or may be learned by practice of the presented embodiments.

According to an aspect of an example embodiment, a semiconductor package may include a first redistribution layer structure, a first set of semiconductor dies on the first redistribution layer structure, a plurality of connection members on the first redistribution layer structure and around the first set of semiconductor dies, a molding material on the first redistribution layer structure, the molding material covering the first set of semiconductor dies and at least partially surrounding the plurality of connection members, a second redistribution layer structure on the molding material, a second set of semiconductor dies on the second redistribution layer structure, and a dummy structure on the second redistribution layer structure and between a first semiconductor die of the second set of semiconductor dies and a second semiconductor die of the second set of semiconductor dies.

According to an aspect of an example embodiment, a semiconductor package may include a first redistribution layer structure, a first semiconductor die on the first redistribution layer structure, a second semiconductor die on the first redistribution layer structure and adjacent to the first semiconductor die, a plurality of first connection members on the first redistribution layer structure, and around the first semiconductor die and the second semiconductor die, a first molding material on the first redistribution layer structure, the first molding material covering the first semiconductor die and the second semiconductor die, and the first molding material at least partially surrounding the plurality of first connection members, a second redistribution layer structure on the first molding material, the second redistribution layer structure connected to the first redistribution layer structure through the plurality of first connection members, a third semiconductor die on the second redistribution layer structure, a fourth semiconductor die on the second redistribution layer structure, a dummy structure on the second redistribution layer structure, and between the third semiconductor die and the fourth semiconductor die, and a second molding material on the second redistribution layer structure and at least partially surrounding the third semiconductor die, the fourth semiconductor die, and the dummy structure.

According to an aspect of an example embodiment, a manufacturing method of a semiconductor package may include forming a first redistribution layer structure on a carrier, forming a plurality of connection members on the first redistribution layer structure, providing a first set of semiconductor dies on the first redistribution layer structure, molding the plurality of connection members and the first set of semiconductor dies with a first molding material on the first redistribution layer structure, forming a second redistribution layer structure on the first molding material, providing a dummy structure on the second redistribution layer structure, and providing a second set of semiconductor dies on the second redistribution layer structure, where the dummy structure is provided between a first semiconductor die of the second set of semiconductor dies and a second semiconductor die of the second set of semiconductor dies.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a cross-sectional view illustrating a semiconductor package according to one or more example embodiments.

FIG. 2 is a plan view illustrating a semiconductor package of FIG. 1 taken along a line A-A′ according to one or more example embodiments.

FIG. 3 is a plan view illustrating a semiconductor package of FIG. 1 taken along a line B-B′ according to one or more example embodiments.

FIG. 4 is a plan view illustrating a semiconductor package according to one or more example embodiments.

FIG. 5 is a plan view illustrating a semiconductor package according to one or more example embodiments.

FIG. 6 is a plan view illustrating a semiconductor package according to one or more example embodiments.

FIG. 7 is a plan view illustrating a semiconductor package according to one or more example embodiments.

FIG. 8 is a plan view illustrating a semiconductor package according to one or more example embodiments.

FIG. 9 is a plan view illustrating a semiconductor package according to one or more example embodiments.

FIG. 10 to FIG. 21 are cross-sectional views illustrating a method of manufacturing a semiconductor package according to one or more example embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Further, since sizes and thicknesses of constituent members shown in the accompanying drawings are arbitrarily given for better understanding and ease of description, example embodiments are not limited to the illustrated sizes and thicknesses.

Throughout this specification and the claims that follow, when it is described that an element is “coupled” to another element, the element may be “directly coupled” to the other element or “electrically coupled” to the other element through a third element. In addition, unless explicitly described to the contrary, the word “comprise”, and variations such as “comprises” or “comprising”, will be understood to imply the inclusion of stated elements but not the exclusion of any other elements.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Hereinafter, a semiconductor package 100 and a manufacturing method of a semiconductor package 100 according to example embodiments are described with reference to accompanying drawings. In the description below, reference may be made to a singular component and a plurality of components interchangeably according to the context of the aspect being described, and such description does not limit the embodiments to singular/plural features in this manner.

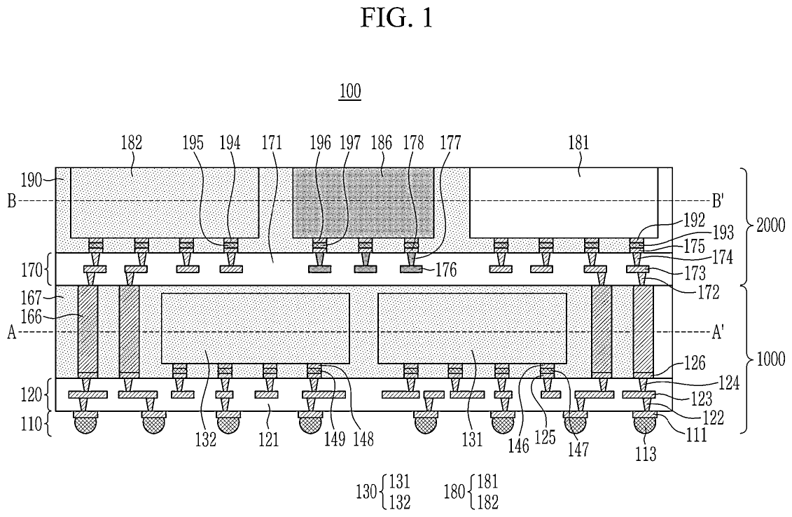

FIG. 1 is a cross-sectional view illustrating a semiconductor package 100 according to one or more example embodiments.

Referring to FIG. 1, a semiconductor package 100 may include a lower structure 1000 and an upper structure 2000. The semiconductor package 100 may include an external connection structure 110, a first redistribution layer structure 120 (e.g., a front side redistribution layer structure), a first set of semiconductor dies 130, first connection members 166 (e.g., conductive posts), a first molding material 167, a second redistribution layer structure 170 (e.g., a back side redistribution layer structure; a second set of semiconductor dies 180, a dummy structure 186, and a second molding material 190. In some embodiments, the semiconductor package 100 may include a package on package (PoP). In some embodiments, the semiconductor package 100 may include a fan-out wafer level package (FOWLP) or a fan-out panel level package (FOPLP).

The external connection structure 110 may be disposed on the bottom surface of the first redistribution layer structure 120. The external connection structure 110 may include conductive pads 111 and external connection members 113. The conductive pad 111 may electrically connect the first redistribution via 122 of the first redistribution layer structure 120 to the external connection member 113. The external connection member 113 may electrically connect the semiconductor package 100 to an external device.

The first redistribution layer structure 120 may include a first dielectric layer 121, first redistribution vias 122, first redistribution lines 123, and second redistribution vias 124 in the first dielectric layer 121, and first bonding pads 125 and second bonding pads 126 on the first dielectric layer 121. In some embodiments, a first redistribution layer structure 120 including fewer or more redistribution lines, redistribution vias, and bonding pads may be implemented.

The first dielectric layer 121 may protect and insulate the first redistribution vias 122, the first redistribution lines 123, and the second redistribution vias 124. The first set of semiconductor dies 130 and the connection members 166 may be disposed on the upper surface of the first dielectric layer 121. The connection members 166 may include conductive posts. The external connection structure 110 may be disposed on the bottom surface of the first dielectric layer 121.

The first redistribution via 122 may be disposed between the first redistribution line 123 and the conductive pad 111. The first redistribution via 122 may electrically connect the first redistribution line 123 to the external connection member 113 connected to the conductive pad 111 in the vertical direction. The first redistribution line 123 may be disposed between the first redistribution via 122 and the second redistribution via 124. The first redistribution line 123 may electrically connect the first redistribution via 122 and the second redistribution via 124 in the horizontal direction. The second redistribution via 124 may be disposed between the first bonding pad 125 and the first redistribution line 123, or between the second bonding pad 126 and the first redistribution line 123. The second redistribution via 124 may electrically connect the first bonding pad 125 to the first redistribution line 123, or the second bonding pad 126 to the first redistribution line 123 in the vertical direction.

The first bonding pad 125 may be disposed between the second redistribution via 124 and the connection member 147, or between the second redistribution via 124 and the connection member 149. The first bonding pad 125 may electrically connect the connection member 147 to the second redistribution via 124, and the connection member 149 to the second redistribution via 124 in the vertical direction.

The second bonding pad 126 may be disposed between the second redistribution via 124 and the connection member 166. The second bonding pad 126 may electrically connect the connection member 166 to the second redistribution via 124 in the vertical direction.

The first set of semiconductor dies 130 may be disposed on the first redistribution layer structure 120. The first set of semiconductor dies 130 may include a plurality of semiconductor dies. FIG. 1 to FIG. 3 show the first semiconductor die 131 and the second semiconductor die 132, but the first set of the semiconductor dies 130 according to some embodiments may include a larger number of semiconductor dies.

The first semiconductor die 131 and the second semiconductor die 132 may be disposed adjacent to each other on the first redistribution layer structure 120. When the semiconductor dies are stacked vertically, the thickness of the semiconductor structure may increase, such that it may be difficult to release heat accumulated within the structure to the outside. Therefore, according to some embodiments, by disposing the first semiconductor die 131 and the second semiconductor die 132 adjacent to each other rather than vertically stacking on the first redistribution layer structure 120, heat accumulated in the structure may be more effectively released to the outside. Additionally, according to some embodiments, compared to a structure in which the semiconductor dies are vertically stacked, the vertical size of the semiconductor package may be reduced.

In some embodiments, no other structures may be disposed between the first semiconductor die 131 and the second semiconductor die 132. As a result, the horizontal size of the semiconductor package may be reduced by disposing the first semiconductor die 131 and the second semiconductor die 132 in positions adjacent to each other. Considering the gap that may be tolerated when mounting the first semiconductor die 131 and the second semiconductor die 132 on the first redistribution layer structure, the gap between the first semiconductor die 131 and the second semiconductor die 132 may be about 15 μm or more.

The first semiconductor die 131 may include a logic circuit. In some embodiments, the first semiconductor die 131 may include at least one of a central processing unit (CPU) and a graphic processing unit (GPU). The first semiconductor die 131 may be surrounded by or at least partially surrounded by the first molding material 167. The first semiconductor die 131 may be electrically connected to the first redistribution layer structure 120 through connection pads 146 and connection members 147. The connection pad 146 may be disposed between the first semiconductor die 131 and the connection member 147. The connection pad 146 may electrically connect the first semiconductor die 131 to the connection member 147. The connection member 147 may be disposed between the connection pad 146 and the second redistribution via 124 of the first redistribution layer structure 120. The connection member 147 may electrically connect the connection pad 146 to the second redistribution via 124 of first redistribution layer structure 120.

The second semiconductor die 132 may be disposed adjacent to each other with the first semiconductor die 131. In some embodiments, the second semiconductor die 132 may include a static random access memory (SRAM). The second semiconductor die 132 may be surrounded by or at least partially surrounded by the first molding material 167. The second semiconductor die 132 may be electrically connected to the first redistribution layer structure 120 through the connection pads 148 and the connection members 149. The connection pad 148 may be disposed between the second semiconductor die 132 and the connection member 149. The connection pad 148 may electrically connect the second semiconductor die 132 to the connection member 149. The connection member 149 may be disposed between the connection pad 148 and the second redistribution via 124 of the first redistribution layer structure 120. The connection member 149 may electrically connect the connection pad 148 to the second redistribution via 124 of the first redistribution layer structure 120.

The connection members 166 may be disposed on the upper surface of the first redistribution layer structure 120. The connection members 166 may be disposed around the first set of semiconductor dies 130. The connection members 166 may not be disposed between the semiconductor dies in the first set of semiconductor dies 130. The connection member 166 may be disposed between the third redistribution via 172 and the second bonding pad 126 of the second redistribution layer structure 170. The connection member 166 may electrically connect the third redistribution via 172 of the second redistribution layer structure 170 to the second bonding pad 126. The connection member 166 may be disposed and pass through the first molding material 167. The sides of the connection member 166 may be surrounded by or at least partially surrounded by the first molding material 167.

The first molding material 167 may mold (e.g., encapsulate) the first set of semiconductor dies 130 and the connection members 166 on the first redistribution layer structure 120. The first molding material 167 may protect the first set of semiconductor dies 130 and the connection members 166 from the external environment, thereby ensuring an electrical or mechanical stability of the semiconductor package 100.

The second redistribution layer structure 170 may be disposed on the connection members 166 and the first molding material 167. The second redistribution layer structure 170 may include a second dielectric layer 171, third redistribution vias 172, second redistribution lines 173, fourth redistribution vias 174, thermal lines 176, and thermal vias 177 in the second dielectric layer 171, and third bonding pads 175 and thermal bonding pads 178 on the second dielectric layer 171. In some embodiments, a second redistribution layer structure 170 including fewer or more redistribution lines, redistribution vias, and bonding pads may be implemented.

The second dielectric layer 171 may protect and insulate the third redistribution vias 172, the second redistribution lines 173, the fourth redistribution vias 174, the thermal lines 176, and the thermal vias 177. The second set of semiconductor dies 180, the dummy structure 186, and the second molding material 190 may be disposed on the upper surface of the second dielectric layer 171. The connection members 166 and the first molding material 167 may be disposed on the bottom surface of the second dielectric layer 171.

The third redistribution via 172 may be disposed between the connection member 166 and the second redistribution line 173. The third redistribution via 172 may electrically connect the second redistribution line 173 to the connection member 166 in the vertical direction. The second redistribution line 173 may be disposed between the third redistribution via 172 and the fourth redistribution via 174. The second redistribution line 173 may electrically connect the third redistribution via 172 and the fourth redistribution via 174 in the horizontal direction. The fourth redistribution via 174 may be disposed between the second redistribution line 173 and the third bonding pad 175. The fourth redistribution via 174 may electrically connect the third bonding pad 175 to the second redistribution line 173 in the vertical direction. The third bonding pad 175 may be disposed between the fourth redistribution via 174 and the connection member 193, or between the fourth redistribution via 174 and the connection member 195. The third bonding pad 175 may electrically connect the connection member 193 to the fourth redistribution via 174, or the connection member 195 to the fourth redistribution via 174.

The thermal lines 176 may be positioned at the same level as the second redistribution lines 173. The thermal line 176 may be disposed between the third redistribution via 172 and the thermal via 177. The thermal line 176 may connect the third redistribution via 172 connected to the ground and the thermal via 177 in the horizontal direction. The thermal vias 177 may be positioned at the same level as the fourth redistribution vias 174. The thermal via 177 may be disposed between the thermal line 176 and the thermal bonding pad 178. The thermal via 177 may connect the thermal bonding pad 178 to the thermal line 176 in the vertical direction. The thermal bonding pads 178 may be positioned at the same level as the third bonding pads 175. The thermal bonding pad 178 may be disposed between the thermal via 177 and the connection member 197. The thermal bonding pad 178 may electrically connect the connection member 197 to the thermal via 177. In some embodiments, the third redistribution vias 172, the second redistribution lines 173, the fourth redistribution vias 174, and the third bonding pads 175 may be electrically connected to the first set of semiconductor dies 130, the second set of the second set of semiconductor dies 180, a power source, or a ground through the connection members 166, the thermal lines 176, the thermal vias 177, and the thermal bonding pads 178 are electrically insulated or only connected to the ground.

The thermal line 176, thermal via 177, and thermal bonding pad 178 may be a part of the path that releases heat within the semiconductor package 100 to the outside through the dummy structure 186. The thermal line 176, thermal via 177, and thermal bonding pad 178 may include materials with higher thermal conductivity than the third redistribution vias 172, second redistribution lines 173, fourth redistribution vias 174, and third bonding pads 175.

The second set of semiconductor dies 180 may be disposed on the second redistribution layer structure 170. The second set of semiconductor dies 180 may be electrically connected to the second redistribution layer structure 170. The second set of semiconductor dies 180 may include a plurality of semiconductor dies. In FIG. 1 to FIG. 3, the third semiconductor die 181 and the fourth semiconductor die 182 are shown, but the second set of semiconductor dies 180 according to some embodiments may include a larger number of semiconductor dies.

The third semiconductor die 181 and the fourth semiconductor die 182 may be disposed adjacent to each other on the second redistribution layer structure 170. The dummy structure 186 may be disposed between the third semiconductor die 181 and the fourth semiconductor die 182. In some embodiments, the third semiconductor die 181 and the fourth semiconductor die 182 may include a single chip, such as a dynamic random access memory (DRAM), or multiple chips, such as high bandwidth memory (HBM).

The third semiconductor die 181 and the fourth semiconductor die 182 may be surrounded by or at least partially surrounded by the second molding material 190. The upper surface of the third semiconductor die 181 and the fourth semiconductor die 182 may be exposed from the second molding material 190, respectively. The third semiconductor die 181 may be electrically connected to the second redistribution layer structure 170 through the connection pads 192 and the connection members 193. The connection pad 192 may be disposed between the third semiconductor die 181 and the connection member 193. The connection pad 192 may electrically connect the third semiconductor die 181 to the connection member 193. The connection member 193 may be disposed between the connection pad 192 and the third bonding pad 175 of the second redistribution layer structure 170. The connection member 193 may electrically connect the connection pad 192 to the third bonding pad 175 of the second redistribution layer structure 170. The fourth semiconductor die 182 may be electrically connected to the second redistribution layer structure 170 through the connection pads 194 and the connection members 195. The connection pad 194 may be disposed between the fourth semiconductor die 182 and the connection member 195. The connection pad 194 may electrically connect the fourth semiconductor die 182 to the connection member 195. The connection member 195 may be disposed between the connection pad 194 and the third bonding pad 175 of the second redistribution layer structure 170. The connection member 195 may electrically connect the connection pad 194 to the third bonding pad 175 of the second redistribution layer structure 170.

The dummy structure 186 may be disposed on the second redistribution layer structure 170. The dummy structure 186 may be disposed between the third semiconductor die 181 and the fourth semiconductor die 182. The dummy structure 186, the third semiconductor die 181, and the fourth semiconductor die 182 may be disposed in positions adjacent to each other. Accordingly, the horizontal size of the semiconductor package may be reduced. Considering the allowable interval when mounting the dummy structure 186, third semiconductor die 181, and fourth semiconductor die 182 on the second redistribution layer structure, the interval between the dummy structure 186 and the third semiconductor die 181, and between the interval between the dummy structure 186 and the fourth semiconductor die 182 may be of about 15 μm or more. The dummy structure 186 may be surrounded by or at least partially surrounded by the second molding material 190. The upper surface of the dummy structure 186 may be exposed from the second molding material 190. In some embodiments, the dummy structure 186 may be electrically insulated. In some embodiments, the dummy structure 186 may include a memory die. In some embodiments, the dummy structure 186 may include a capacitor. The dummy structure 186 may be electrically connected to the second redistribution layer structure 170 through the connection pads 196 and the connection members 197. The connection pad 196 may be disposed between the dummy structure 186 and the connection member 197. The connection pad 196 may electrically connect the dummy structure 186 to the connection member 197. The connection member 197 may be disposed between the connection pad 196 and the thermal bonding pads 178 of the second redistribution layer structure 170. The connection member 197 may electrically connect the connection pad 196 to the thermal bonding pads 178 of the second redistribution layer structure 170.

Conventionally, in the upper structure of a multi-chip fan-out wafer level package, because the space between the semiconductor chips is filled only with the molding material without any other structure, the multi-chip fan-out wafer level package has low strength, and due to the low strength, a bending could occur in the multi-chip fan-out wafer level package. However, according to some embodiments, by disposing the dummy structure 186 between the third semiconductor die 181 and the fourth semiconductor die 182, the strength of the semiconductor package 100 may be increased and a bending may be prevented.

The dummy structure 186 may be a heat dissipation structure. In some embodiments, the dummy structure 186 may be formed of a conductive material with high thermal conductivity. In some embodiments, the dummy structure 186 may include copper, aluminum, gold, silver, iron, or Stainless Steel (SUS). In some embodiments, the dummy structure 186 may be formed of a silicon material with high thermal conductivity compared to the second molding material 190. In this way, the dummy structure 186 may be implemented as a heat dissipation structure, the redistribution line of the second redistribution layer structure 170 may be formed as a thermal line 176, and the via of the second redistribution layer structure 170 may be formed as a thermal via 177. The heat generated in the first set of semiconductor dies 130 of the lower structure 1000 may be released to the outside through a path passing through the dummy structure 186 through the thermal lines 176 and the thermal vias 177 of the second redistribution layer structure 170. This may improve a thermal characteristic of the semiconductor package. In some embodiments, the dummy structure 186 may be connected to the ground.

The second molding material 190 may mold (e.g., encapsulate) the second set of semiconductor dies 180 and the dummy structure 186 on the second redistribution layer structure 170. The second molding material 190 may protect the second set of semiconductor dies 180 and the dummy structure 186 from the external environment, thereby ensuring an electrical or mechanical stability of the semiconductor package 100.

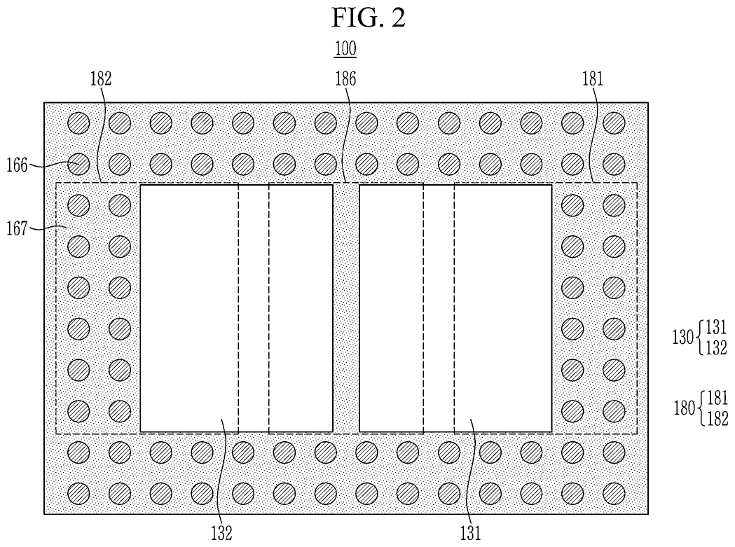

FIG. 2 is a plan view illustrating the semiconductor package 100 of FIG. 1 taken along a line A-A′ according to one or more example embodiments.

Referring to FIG. 2, in the lower structure 1000, the first set of semiconductor dies 130 may include a first semiconductor die 131 and a second semiconductor die 132. To depict the overlapping arrangement of the first semiconductor die 131 and the second semiconductor die 132 in the lower structure 1000, and the third semiconductor die 181, the fourth semiconductor die 182, and the dummy structure 186 in the upper structure 2000, outlines of the third semiconductor die 181, the fourth semiconductor die 182, and the dummy structure 186 of the upper structure 2000, are shown as a dotted line.

According to some embodiments, in the lower structure 1000 of the semiconductor package 100, all (or most of) the connection members 166 connecting the first redistribution layer structure 120 and the second redistribution layer structure 170 may be disposed on the edge of the package, and the first semiconductor die 131 and the second semiconductor die 132 may be disposed adjacent to each other. Additionally, in the upper structure 2000 of the semiconductor package 100, the third semiconductor die 181 and the fourth semiconductor die 182 may be disposed at the edge of the semiconductor package 100 to be spaced apart from each other, and the dummy structure 186 may be disposed between the third semiconductor die 181 and the fourth semiconductor die 182. Due to this structure of the semiconductor package 100, the strength of the semiconductor package 100 may be improved and the bending of the package may be reduced. To have the above-described structure, a portion of the dummy structure 186 and a portion of the third semiconductor die 181 may overlap the first semiconductor die 131. A portion of the dummy structure 186 and a portion of the fourth semiconductor die 182 may overlap the second semiconductor die 132.

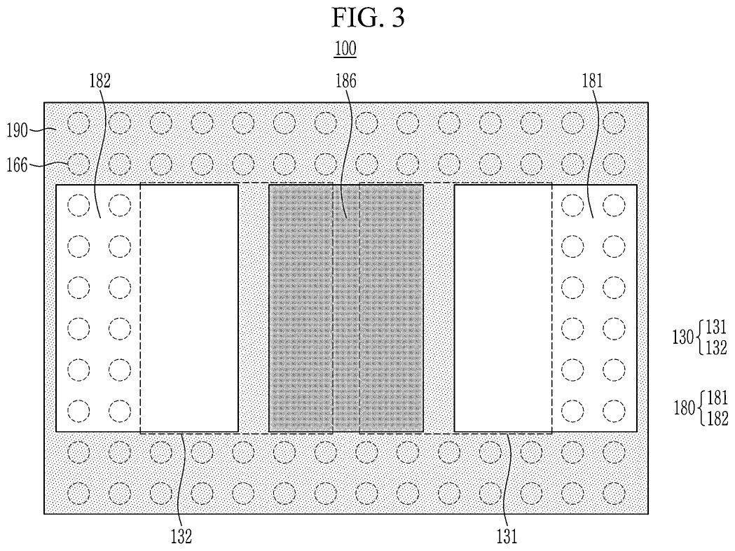

FIG. 3 is a plan view illustrating the semiconductor package 100 of FIG. 1 taken along a line B-B′ according to one or more example embodiments.

Referring to FIG. 3, in the upper structure 2000, the second set of semiconductor dies 180 may include a third semiconductor die 181 and a fourth semiconductor die 182. To depict the overlapping arrangement of the first semiconductor die 131 and the second semiconductor die 132 in the lower structure 1000, and the third semiconductor die 181, the fourth semiconductor die 182, and the dummy structure 186 in the upper structure 2000, outlines of the first semiconductor die 131, the second semiconductor die 132, and the connection members 166 of the lower structure 1000 are shown as a dotted line.

The third semiconductor die 181 may overlap a portion of the first semiconductor die 131. The dummy structure 186 may overlap a portion of the first semiconductor die 131 and a portion of the second semiconductor die 132. The fourth semiconductor die 182 may overlap a portion of the second semiconductor die 132.

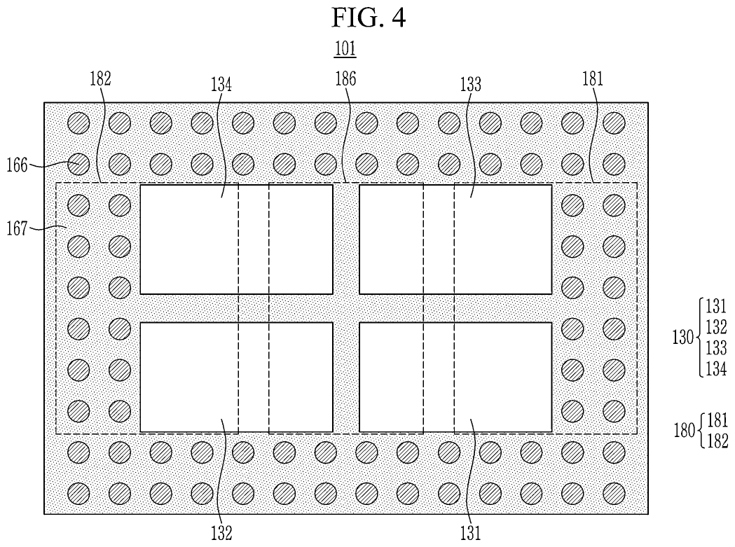

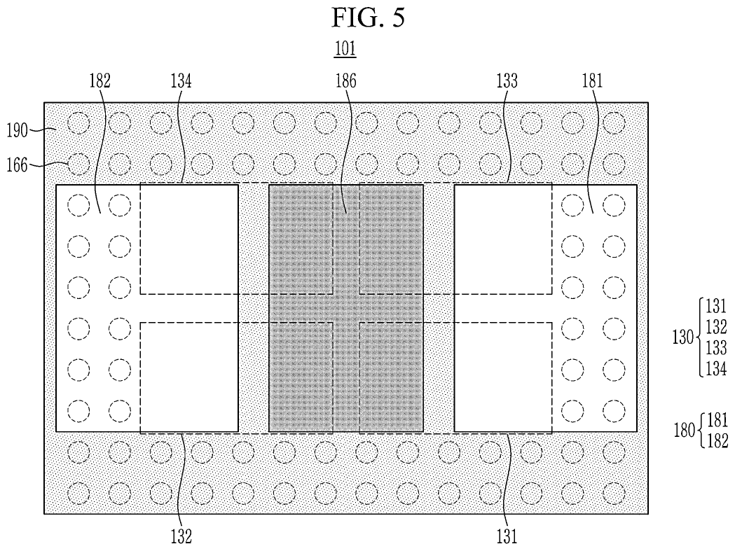

The example embodiments described in relation to FIGS. 4-9 include plan views similar to those views of FIGS. 2-3. That is, FIGS. 4, 6 and 8 include plan views of semiconductor packages 101, 102 and 103 along a line that is similar in position to line A-A′ of FIG. 1, and FIGS. 5, 7 and 9 include plan views of semiconductor packages 101, 102 and 103 along a line that is similar in position to line B-B′ of FIG. 1.

FIG. 4 is a plan view illustrating a semiconductor package 101 according to one or more example embodiments.

Referring to FIG. 4, in the lower structure 1000, the first set of semiconductor dies 130 may include a first semiconductor die 131, a second semiconductor die 132, a fifth semiconductor die 133, and a sixth semiconductor die 134. To depict the overlapping arrangement of the first semiconductor die 131, the second semiconductor die 132, the fifth semiconductor die 133, and the sixth semiconductor die 134 in the lower structure 1000, and the third semiconductor die 181, the fourth semiconductor die 182, and the dummy structure 186 in the upper structure 2000, outlines of the third semiconductor die 181, the fourth semiconductor die 182, and the dummy structure 186 of the upper structure 2000 are shown as a dotted line.

According to some embodiments, in the lower structure 1000 of the semiconductor package 101, all (or most) of the connection members 166 connecting the first redistribution layer structure 120 and the second redistribution layer structure 170 may be disposed at the edge of the package, and the first semiconductor die 131, the second semiconductor die 132, the fifth semiconductor die 133, and the sixth semiconductor die 134 may be disposed to be adjacent to each other. Additionally, in the upper structure 2000 of the semiconductor package 101, the third semiconductor die 181 and the fourth semiconductor die 182 may be disposed at the edge of the semiconductor package 101 to be spaced apart from each other, and the dummy structure 186 may be disposed between the third semiconductor die 181 and the fourth semiconductor die 182. Due to this structure of the semiconductor package 101, the strength of the semiconductor package 101 may be improved and the bending of the package may be reduced.

A portion of the dummy structure 186 and a portion of the third semiconductor die 181 may overlap the first semiconductor die 131. A portion of the dummy structure 186a portion of the fourth semiconductor die 182 may overlap the second semiconductor die 132. Additionally, a portion of the dummy structure 186 and a portion of the third semiconductor die 181 may overlap the fifth semiconductor die 133. A portion of the dummy structure 186 and a portion of the fourth semiconductor die 182 may overlap the sixth semiconductor die 134.

FIG. 5 is a plan view illustrating a semiconductor package 101 according to one or more example embodiments.

Referring to FIG. 5, in the upper structure 2000, the second set of semiconductor dies 180 may include a third semiconductor die 181 and a fourth semiconductor die 182. To show the overlapping relationship of the first semiconductor die 131, the second semiconductor die 132, the fifth semiconductor die 133, and the sixth semiconductor die 134 in the lower structure 1000, and the third semiconductor die 181, the fourth semiconductor die 182, and the dummy structure 186 in the upper structure 2000, outlines of the first semiconductor die 131, the second semiconductor die 132, the fifth semiconductor die 133, the sixth semiconductor die 134, and the connection members 166 of the lower structure 1000 are shown as a dotted line.

The third semiconductor die 181 may overlap a portion of the first semiconductor die 131 and a portion of the fifth semiconductor die 133. The dummy structure 186 may overlap a portion of the first semiconductor die 131, a portion of the second semiconductor die 132, a portion of the fifth semiconductor die 133, and a portion of the sixth semiconductor die 134. The fourth semiconductor die 182 may overlap a portion of the second semiconductor die 132 and the sixth semiconductor die 134.

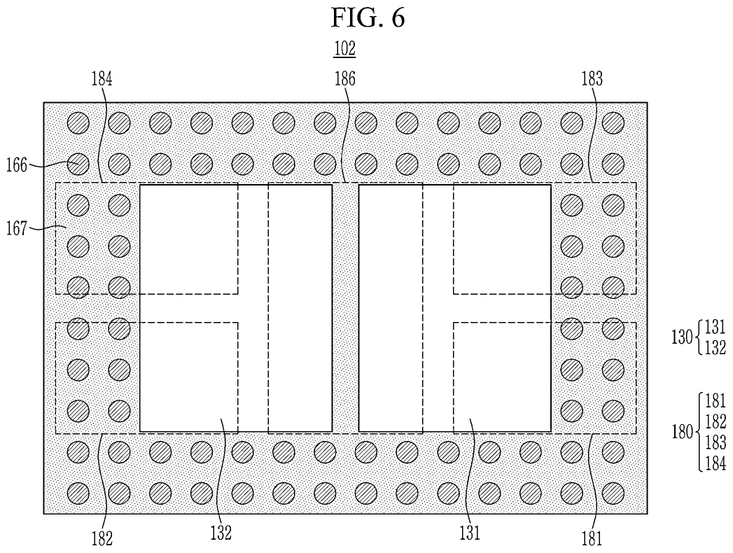

FIG. 6 is a plan view illustrating a semiconductor package 102 according to one or more example embodiments.

Referring to FIG. 6, in the lower structure 1000, the first set of semiconductor dies 130 may include a first semiconductor die 131 and a second semiconductor die 132. To show the overlapping relationship of the first semiconductor die 131 and the second semiconductor die 132 in the lower structure 1000, and the third semiconductor die 181, the fourth semiconductor die 182, the seventh semiconductor die 183, the eighth semiconductor die 184, and the dummy structure 186 in the upper structure 2000, outlines of the third semiconductor die 181, the fourth semiconductor die 182, the seventh semiconductor die 183, the eighth semiconductor die 184, and the dummy structure 186 in the upper structure 2000 is shown as a dotted line.

According to some embodiments, in the lower structure 1000 of the semiconductor package 102, all (or most) of the connection members 166 connecting the first redistribution layer structure 120 and the second redistribution layer structure 170 may be disposed at the edge of the package, and the first semiconductor die 131 and the second semiconductor die 132 may be disposed adjacent to each other. Additionally, in the upper structure 2000 of the semiconductor package 102, the third semiconductor die 181 and the seventh semiconductor die 183 disposed on the first side, and the fourth semiconductor die 182 and the eighth semiconductor die 184 disposed on the second side may be positioned at the edges of the semiconductor package 102 to be spaced apart from each other, the dummy structure 186 may be disposed between the third semiconductor die 181 and the seventh semiconductor die 183 disposed on the first side and the fourth semiconductor die 182 and the eighth semiconductor die 184 disposed on the second side. Due to this structure of the semiconductor package 102, the strength of the semiconductor package 102 may be improved and the bending of the package may be reduced.

A portion of the dummy structure 186, a portion of the third semiconductor die 181, and a portion of the seventh semiconductor die 183 may overlap the first semiconductor die 131. A portion of the dummy structure 186, a portion of the fourth semiconductor die 182, and a portion of the eighth semiconductor die 184 may overlap the second semiconductor die 132.

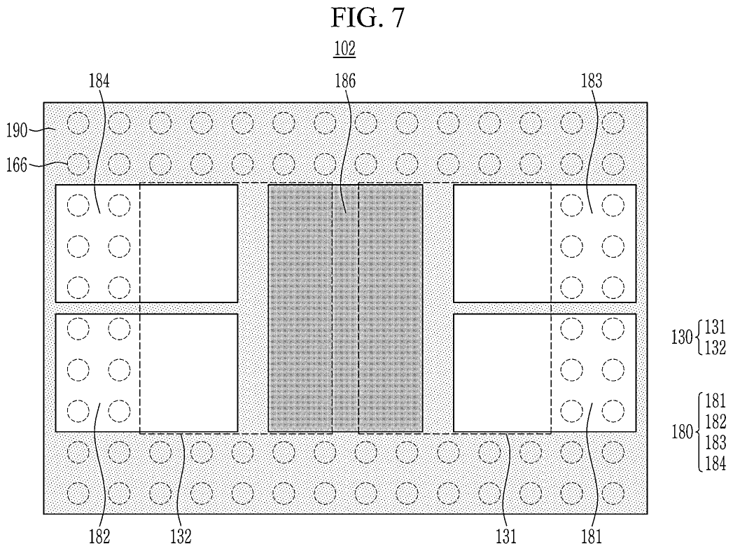

FIG. 7 is a plan view illustrating a semiconductor package 102 according to one or more example embodiments.

Referring to FIG. 7, in the upper structure 2000, the second set of semiconductor dies 180 may include a third semiconductor die 181, a fourth semiconductor die 182, a seventh semiconductor die 183, and an eighth semiconductor die 184. To show the overlapping relationship of the first semiconductor die 131 and the second semiconductor die 132 in the lower structure 1000, and the third semiconductor die 181, the fourth semiconductor die 182, the seventh semiconductor die 183, the eighth semiconductor die 184, and the dummy structure 186 in the upper structure 2000, outlines of the first semiconductor die 131, the second semiconductor die 132, and the connection members 166 of the lower structure 1000 are shown as a dotted line.

The third semiconductor die 181 may overlap a portion of the first semiconductor die 131. The dummy structure 186 may overlap a portion of the first semiconductor die 131 and a portion of the second semiconductor die 132. The fourth semiconductor die 182 may overlap a portion of the second semiconductor die 132. The seventh semiconductor die 183 may overlap a portion of the first semiconductor die 131. The eighth semiconductor die 184 may overlap a portion of the second semiconductor die 132.

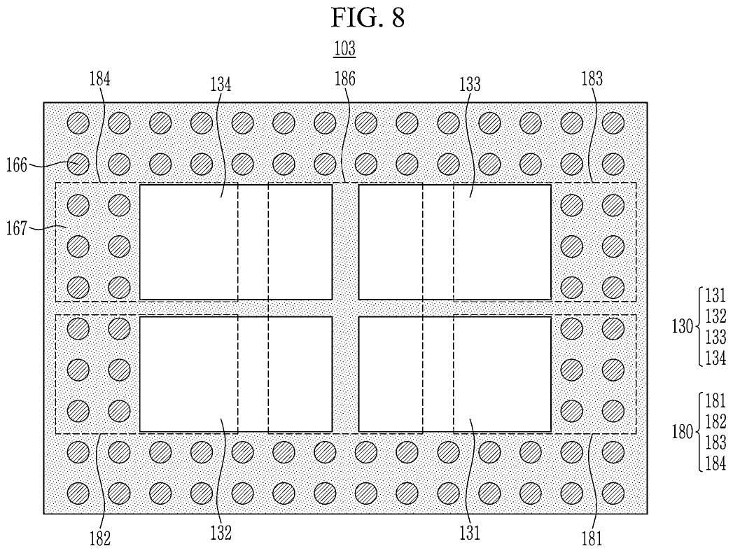

FIG. 8 is a plan view illustrating a semiconductor package 103 according to one or more example embodiments.

Referring to FIG. 8, in the lower structure 1000, the first set of semiconductor dies 130 may include a first semiconductor die 131, a second semiconductor die 132, a fifth semiconductor die 133, and a sixth semiconductor die 134. To show the overlapping relationship of the first semiconductor die 131, the second semiconductor die 132, the fifth semiconductor die 133, and the sixth semiconductor die 134 in the lower structure 1000, and the third semiconductor die 181, the fourth semiconductor die 182, the seventh semiconductor die 183, the eighth semiconductor die 184, and the dummy structure 186 in the upper structure 2000, outlines of the third semiconductor die 181, the fourth semiconductor die 182, the seventh semiconductor die 183, the eighth semiconductor die 184, and the dummy structure 186 in the upper structure 2000 are shown as a dotted line.

According to some embodiments, in the lower structure 1000 of semiconductor package 103, all (or most) of the connection members 166 connecting the first redistribution layer structure 120 and the second redistribution layer structure 170 may be disposed at the edge of the package, and the first semiconductor die 131, and the second semiconductor die 132, the fifth semiconductor die 133, and the sixth semiconductor die 134 may be disposed to be adjacent to each other. Additionally, in the upper structure 2000 of the semiconductor package 103, the third semiconductor die 181 and the seventh semiconductor die 183 may be disposed on the first side, and the fourth semiconductor die 182 and the eighth semiconductor die 184 may be disposed on the second side may be disposed at the edge of the semiconductor package 103 so as to be spaced apart from each other. The dummy structure 186 may be disposed between the third semiconductor die 181 and the seventh semiconductor die 183 disposed on the first side and the fourth semiconductor die 182 and the eighth semiconductor die 184 disposed on the second side. Due to this structure of the semiconductor package 103, the strength of the semiconductor package 103 may be improved and the bending of the package may be reduced.

A portion of the dummy structure 186 and a portion of the third semiconductor die 181 may overlap the first semiconductor die 131. A portion of the dummy structure 186 and a portion of the fourth semiconductor die 182 may overlap the second semiconductor die 132. Additionally, a portion of the dummy structure 186 and a portion of the seventh semiconductor die 183 may overlap the fifth semiconductor die 133. A portion of the dummy structure 186 and a portion of the eighth semiconductor die 184 may overlap the sixth semiconductor die 134.

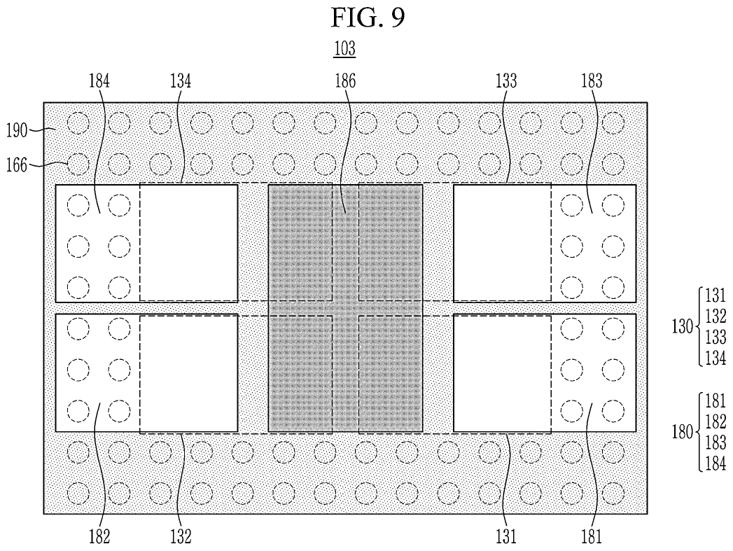

FIG. 9 is a plan view illustrating a semiconductor package 103 according to one or more example embodiments.

Referring to FIG. 9, in the upper structure 2000, the second set of semiconductor dies 180 may include a third semiconductor die 181, a fourth semiconductor die 182, a seventh semiconductor die 183, and an eighth semiconductor die 184. To show the overlapping relationship of the first semiconductor die 131, the second semiconductor die 132, the fifth semiconductor die 133, and the sixth semiconductor die 134 in the lower structure 1000, and the third semiconductor die 181, the fourth semiconductor die 182, the seventh semiconductor die 183, the eighth semiconductor die 184, and the dummy structure 186 in the upper structure 2000, the outline of the first semiconductor die 131, the second semiconductor die 132, the fifth semiconductor die 133, the sixth semiconductor die 134, and the connection members 166 in the lower structure 1000 are shown as a dotted line.

The third semiconductor die 181 may overlap a portion of the first semiconductor die 131. The seventh semiconductor die 183 may overlap a portion of the fifth semiconductor die 133. The dummy structure 186 may overlap a portion of the first semiconductor die 131, a portion of the second semiconductor die 132, a portion of the fifth semiconductor die 133, and a portion of the sixth semiconductor die 134. The fourth semiconductor die 182 may overlap a portion of the second semiconductor die 132. The eighth semiconductor die 184 may overlap a portion of the sixth semiconductor die 134.

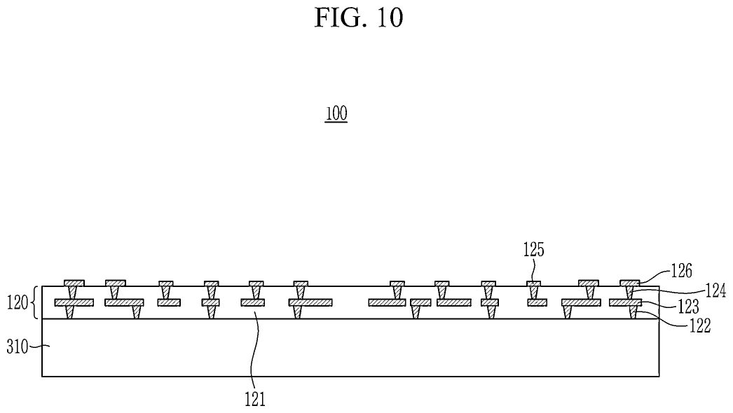

FIG. 10 to FIG. 21 are cross-sectional views illustrating a method of manufacturing a semiconductor package according to one or more example embodiments.

FIG. 10 is a cross-sectional view illustrating an operation of forming a first redistribution layer structure 120 on a carrier 310.

Referring to FIG. 10, the first redistribution layer structure 120 may be formed on the carrier 310. First, the carrier 310 may be provided. In some embodiments, the carrier 310 may include a silicon-based material such as glass or silicon oxide, an organic material, or another material such as aluminum oxide, or any combination of these materials.

Next, the first dielectric layer 121 may be formed on the carrier 310. In some embodiments, the first dielectric layer 121 may include a photosensitive dielectric (a photo imageable dielectric (PID)) used in the redistribution layer process. The photo imageable dielectric may be a material that may form a fine pattern by applying a photolithography process. In some embodiments, the PID may include polyimide-based photoactive polymer, novolac-based photoactive polymer, polybenzoxazole, silicon-based polymer, acrylate-based polymer, or epoxy-based polymer. In some embodiments, the first dielectric layer 121 may be formed of an inorganic dielectric such as silicon nitride, silicon oxide, etc. In some embodiments, the first dielectric layer 121 may be formed by a chemical vapor deposition (CVD) process, an atomic layer deposition (ALD) process, or a plasma-enhanced CVD (PECVD) process.

After forming the first dielectric layer 121, via holes may be formed by selectively etching the first dielectric layer 121, and the via holes may be filled with conducting material to form first redistribution vias 122.

An additional first dielectric layer 121 may be deposited on the first redistribution vias 122 and the first dielectric layer 121, the additionally deposited first dielectric layer 121 may be selectively etched to form openings, and the openings may be filled with a conducting material to form the first redistribution lines 123.

The additional first dielectric layer 121 may be deposited on the first redistribution lines 123 and the first dielectric layer 121, the additionally deposited first dielectric layer 121 may be selectively etched to form via holes, and a conducting material may be filled in the via holes to form second redistribution vias 124.

A photoresist may be additionally deposited on the second redistribution vias 124 and the first dielectric layer 121, the photoresist may be selectively exposed and developed to form a photoresist pattern including openings, and the openings may be filled with a conducting material to form first bonding pads 125 and second bonding pads 126.

In some embodiments, the first redistribution vias 122, the first redistribution lines 123, the second redistribution vias 124, the first bonding pads 125, and the second bonding pads 126 may include at least one of copper, aluminum, tungsten, nickel, gold, tin, titanium, and alloys thereof. In some embodiments, the first redistribution vias 122, the first redistribution lines 123, the second redistribution vias 124, the first bonding pads 125, and the second bonding pads 126 may be formed by performing a sputtering process. In some embodiments, the first redistribution vias 122, the first redistribution lines 123, the second redistribution vias 124, the first bonding pads 125, and the second bonding pads 126 may be formed by performing an electrolytic plating process after forming a seed metal layer.

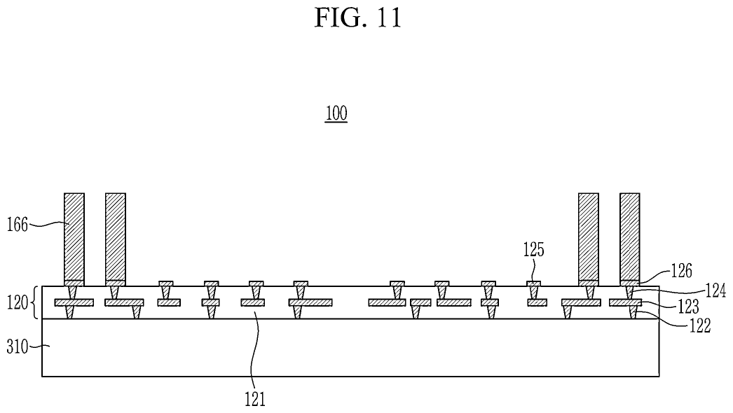

FIG. 11 is a cross-sectional view illustrating an operation of forming connection members 166 on the first redistribution layer structure 120.

Referring to FIG. 11, the connection members 166 may be formed on the second bonding pads 126 of the first redistribution layer structure 120 in the vertical direction. In some embodiments, the connection members 166 may be formed by performing a sputtering process. In some embodiments, the connection members 166 may be formed by forming a seed metal layer and then performing an electrolytic plating process. In some embodiments, the connection member 166 may include at least one of copper, aluminum, tungsten, nickel, gold, silver, chromium, antimony, tin, titanium, and alloys thereof.

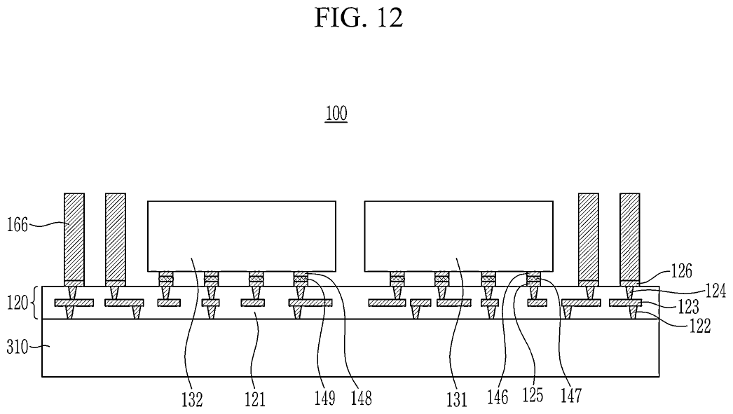

FIG. 12 is a cross-sectional view illustrating an operation of mounting a first semiconductor die 131 and a second semiconductor die 132 on the first redistribution layer structure 120.

Referring to FIG. 12, a first set of semiconductor dies 130 (e.g., a first semiconductor die 131 and a second semiconductor die 132) may be mounted on the first redistribution layer structure 120 by a flip-chip bonding. The connection members 147 on the bottom surface of the first semiconductor die 131 and the connection members 149 on the bottom surface of the second semiconductor die 132 may be bonded to the first bonding pads 125 of the first redistribution layer structure 120, such that the first set of semiconductor dies 130 and the first redistribution layer structure 120 are electrically connected. In some embodiments, the connection members 147 and 149 may include micro bumps or solder balls. In some embodiments, the connection members 147, and 149 may include at least one of tin, silver, lead, nickel, copper, or alloys thereof.

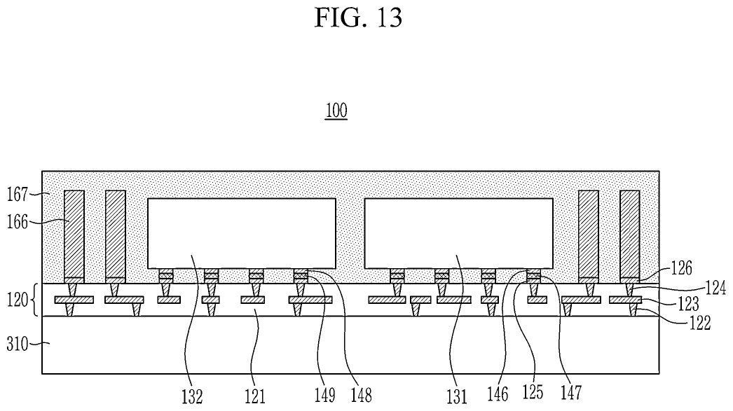

FIG. 13 is a cross-sectional view illustrating an operation of molding the first set of semiconductor dies 130 with a first molding material 167 on the first redistribution layer structure 120.

Referring to FIG. 13, on the first redistribution layer structure 120, the first set of semiconductor dies 130 may be molded with (e.g., encapsulated by) the first molding material 167. In some embodiments, the molding process with the first molding material 167 may include a compression molding or a transfer molding process. In some embodiments, the first molding material 167 may include an epoxy molding compound (EMC).

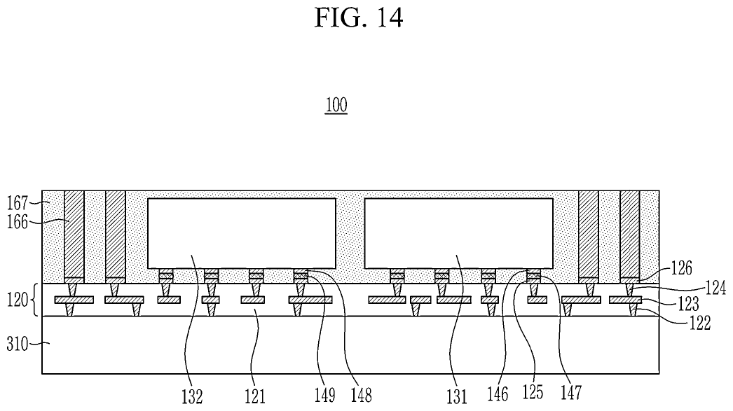

FIG. 14 is a cross-sectional view illustrating an operation of planarizing the first molding material 167.

Referring to FIG. 14, a chemical mechanical polishing (CMP) may be performed to level the upper surface of the first molding material 167. By applying the CMP process, the upper surface of the first molding material 167 may be planarized. After performing the CMP process, the upper surface of the connection members 166 may be exposed.

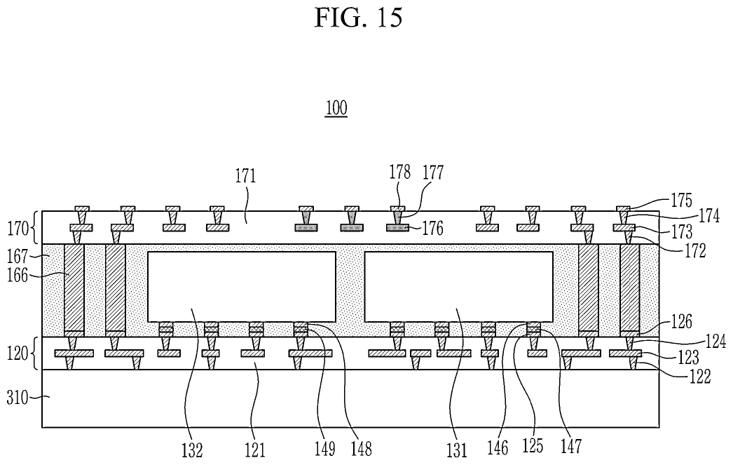

FIG. 15 is a cross-sectional view illustrating an operation of forming a second redistribution layer structure 170 on the connection members 166 and the first molding material 167.

Referring to FIG. 15, a second redistribution layer structure 170 may be formed on the connection members 166 and the first molding material 167.

First, the second dielectric layer 171 may be formed on the connection members 166 and the first molding material 167. In some embodiments, the second dielectric layer 171 may include a PID used in the redistribution layer process. In some embodiments, the PID may include polyimide-based photoactive polymer, novolac-based photoactive polymer, polybenzoxazole, silicon-based polymer, acrylate-based polymer, or epoxy-based polymer. In some embodiments, the second dielectric layer 171 may be formed of an inorganic dielectric such as silicon nitride, silicon oxide, etc. In some embodiments, the second dielectric layer 171 may be formed by a CVD process, an ALD process, or PECVD process.

After forming the second dielectric layer 171, via holes may be formed by selectively etching the second dielectric layer 171, and the via holes may be filled with a conducting material to form third redistribution vias 172.

An additional second dielectric layer 171 may be deposited on the third redistribution vias 172 and the second dielectric layer 171, the additionally deposited second dielectric layer 171 may be selectively etched to form first openings, and a conducting material may be filled in the first opening to form second redistribution lines 173. The additionally deposited second dielectric layer 171 may be selectively etched to form second openings, and the second openings may be filled with a conducting material to form thermal lines 176.

The additional second dielectric layer 171 may be deposited on the second redistribution lines 173 and the second dielectric layer 171, the additionally deposited second dielectric layer 171 may be selectively etched to form first via holes, and conducting material may be filled in the first via holes to form fourth redistribution vias 174. The additionally deposited second dielectric layer 171 may be selectively etched to form second via holes, and the second via holes may be filled with a conducting material to form thermal vias 177.

A photoresist may be additionally deposited on the fourth redistribution vias 174 and the second dielectric layer 171, the photoresist may be selectively exposed and developed to form a first photoresist pattern including openings, and a conducting material may be disposed in the openings to form third bonding pads 175. A photoresist may be additionally deposited, the photoresist may be selectively exposed and developed to form a second photoresist pattern including openings, and the openings may be filled with a conducting material to form thermal bonding pads 178.

In some embodiments, the third redistribution vias 172, the second redistribution lines 173, the fourth redistribution vias 174, and the third bonding pads 175 may include at least one of copper, aluminum, tungsten, nickel, tin, titanium, and alloys thereof. In some embodiments, the thermal lines 176, the thermal vias 177, and the thermal bonding pads 178 may include at least one of gold, silver, copper, and aluminum. In some embodiments, the third redistribution vias 172, the second redistribution lines 173, the fourth redistribution vias 174, the third bonding pads 175, the thermal lines 176, thermal vias 177, and the thermal bonding pads 178 may be formed by performing a sputtering process. In some embodiments, the third redistribution vias 172, the second redistribution lines 173, the fourth redistribution vias 174, the third bonding pads 175, the thermal lines 176, thermal vias 177, and the thermal bonding pads 178 may be formed by performing an electrolytic plating process after forming a seed metal layer.

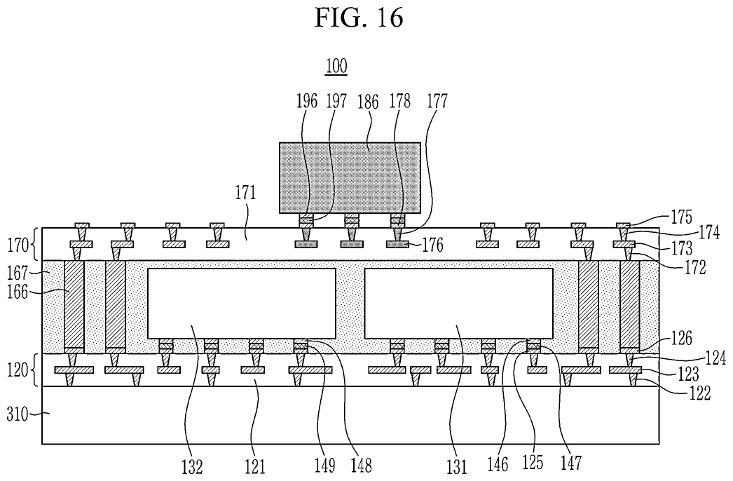

FIG. 16 is a cross-sectional view illustrating an operation of mounting a dummy structure 186 on the second redistribution layer structure 170.

Referring to FIG. 16, the dummy structure 186 may be mounted on the second redistribution layer structure 170 by a flip-chip bonding. The connection members 197 of the bottom surface of the dummy structure 186 may be bonded to the thermal bonding pads 178 of the second redistribution layer structure 170, such that the dummy structure 186 and the second redistribution layer structure 170 are bonded. In some embodiments, the connection member 197 may include a micro bump or a solder ball. In some embodiments, the connection member 197 may include at least one of tin, silver, lead, nickel, copper, or alloys thereof.

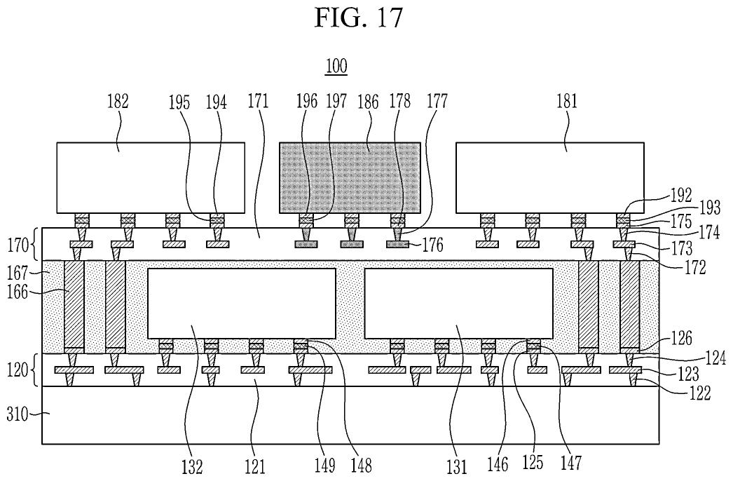

FIG. 17 is a cross-sectional view illustrating an operation of mounting a second set of the semiconductor dies 180 on the second redistribution layer structure 170.

Referring to FIG. 17, the second set of the semiconductor dies 180 (a third semiconductor die 181 and a fourth semiconductor die 182) may be mounted on the second redistribution layer structure 170 by a flip-chip bonding. The connection members 193 of the bottom surface of the third semiconductor die 181 may be bonded to the third bonding pads 175 of the second redistribution layer structure 170, such that the third semiconductor die 181 and the second redistribution layer structure 170 are electrically connected. The connection members 195 of the bottom surface of the fourth semiconductor die 182 may be bonded to the third bonding pads 175 of the second redistribution layer structure 170, such that the fourth semiconductor die 182 and the second redistribution layer structure 170 are electrically connected. In some embodiments, the connection member 193 and 195 may include micro bump or solder ball. In some embodiments, the connection members 193 and 195 may include at least one of tin, silver, lead, nickel, copper, or alloys thereof.

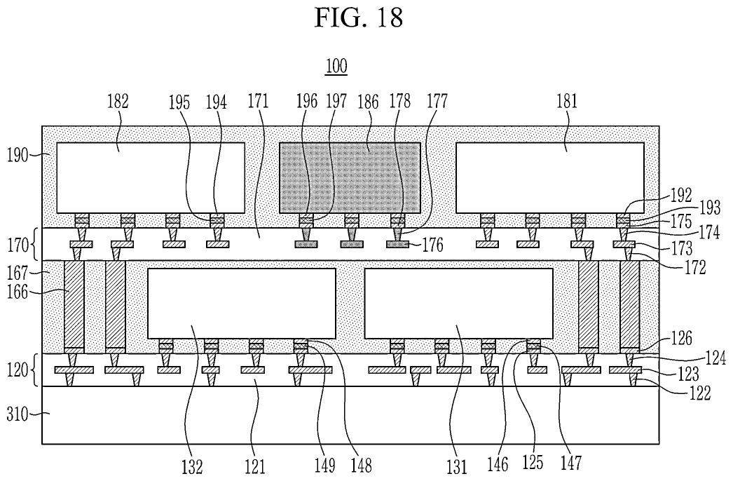

FIG. 18 is a cross-sectional view illustrating an operation of molding the second set of semiconductor dies 180 and the dummy structure 186 with a second molding material 190 on the second redistribution layer structure 170.

Referring to FIG. 18, on the second redistribution layer structure 170, the second set of semiconductor dies 180 and the dummy structure 186 may be molded with (e.g., encapsulated by) the second molding material 190. In some embodiments, the molding process with the second molding material 190 may include a compression molding or a transfer molding process. In some embodiments, the second molding material 190 may include an epoxy molding compound (EMC).

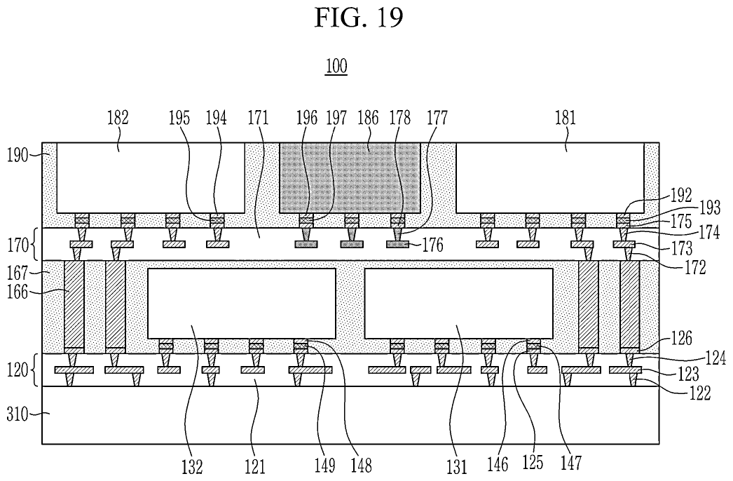

FIG. 19 is a cross-sectional view illustrating an operation of planarizing the second molding material 190.

Referring to FIG. 19, a CMP process may be performed to level the upper surface of the second molding material 190. The CMP process may be applied to planarize the upper surface of the second molding material 190. After performing the CMP process, the upper surface of the second set of semiconductor dies 180 and the upper surface of the dummy structure 186 may be exposed.

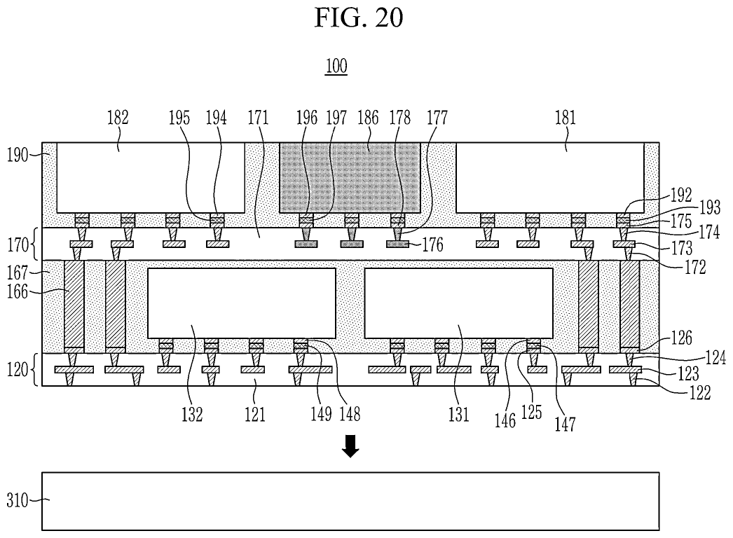

FIG. 20 is a cross-sectional view illustrating an operation of removing the carrier 310 from the first redistribution layer structure 120.

Referring to FIG. 20, the carrier 310 may be removed from the bottom surface of the first redistribution layer structure 120.

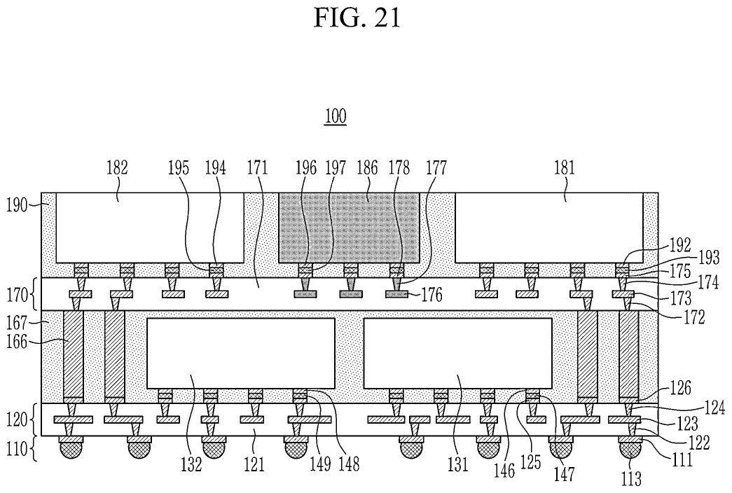

FIG. 21 is a cross-sectional view illustrating an operation of forming an external connection structure 110 on the bottom surface of the first redistribution layer structure 120.

Referring to FIG. 21, the external connection structure 110 may be formed on the bottom surface of the first redistribution layer structure 120. Conductive pads 111 may be formed under the first redistribution vias 122 of the first redistribution layer structure 120, and external connection members 113 may be formed under the conductive pads 111. In some embodiments, the conductive pads 111 may include at least one of copper, nickel, zinc, gold, silver, platinum, palladium, chromium, titanium, and alloys thereof. In some embodiments, the external connection member 113 may include at least one of tin, silver, lead, nickel, copper, or an alloy thereof. In some embodiments, the conductive pad 111 may be formed by performing a sputtering process, or an electrolytic plating process after forming a seed metal layer.

In some embodiments, in the lower structure of the multi-chip fan-out wafer level package, all or most of the conductive posts connecting the front side redistribution layer structure and the back side redistribution layer structure may be disposed at the edge of the package, and the semiconductor chips may be disposed in positions adjacent to each other. Additionally, in the upper structure of the multi-chip fan-out wafer level package, the semiconductor chips may be disposed at the edge of the package, and the dummy structure may be disposed between the semiconductor chips.

Due to the structure of this multi-chip fan-out wafer level package, the strength of the package may be improved and a bending of the package may be reduced.

In addition, as the dummy structure is implemented as a heat dissipation structure, and the via of the back side redistribution layer structure is formed as a thermal via, heat generated in the semiconductor chips of the lower structure may be released to the outside through a path passing through the dummy structure through the thermal via of the back side redistribution layer structure. Accordingly, thermal characteristics of the semiconductor package may be improved.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor package comprising:
a first redistribution layer structure;
a first set of semiconductor dies on the first redistribution layer structure;
a plurality of connection members on the first redistribution layer structure and around the first set of semiconductor dies;
a molding material on the first redistribution layer structure, the molding material covering the first set of semiconductor dies and at least partially surrounding the plurality of connection members;
a second redistribution layer structure on the molding material;
a second set of semiconductor dies on the second redistribution layer structure; and
a dummy structure on the second redistribution layer structure and between a first semiconductor die of the second set of semiconductor dies and a second semiconductor die of the second set of semiconductor dies.

2. The semiconductor package of claim 1, wherein the dummy structure is configured as a heat dissipation structure.

3. The semiconductor package of claim 2, wherein the dummy structure comprises copper, aluminum, gold, silver, iron or Stainless Steel (SUS).

4. The semiconductor package of claim 2, wherein the dummy structure comprises silicon.

5. The semiconductor package of claim 2, wherein the second redistribution layer structure comprises a plurality of redistribution vias and a plurality of thermal vias.

6. The semiconductor package of claim 5, wherein the dummy structure is connected to the plurality of thermal vias.

7. The semiconductor package of claim 6, wherein the plurality of thermal vias are connected to a ground.

8. The semiconductor package of claim 5, wherein the plurality of thermal vias comprise at least one of gold, silver, copper, and aluminum.

9. The semiconductor package of claim 5, wherein the first semiconductor die of the second set of semiconductor dies is connected to first redistribution vias of the plurality of redistribution vias, and
wherein the second semiconductor die of the second set of semiconductor dies is connected to second redistribution vias of the plurality of redistribution vias.

10. The semiconductor package of claim 9, wherein the plurality of redistribution vias are connected to the first set of semiconductor dies through the plurality of connection members.

11. The semiconductor package of claim 5, wherein the plurality of redistribution vias comprise copper.

12. The semiconductor package of claim 1, wherein the dummy structure comprises a memory die.

13. The semiconductor package of claim 1, wherein the dummy structure comprises a capacitor.

14. A semiconductor package comprising:
a first redistribution layer structure;
a first semiconductor die on the first redistribution layer structure;
a second semiconductor die on the first redistribution layer structure and adjacent to the first semiconductor die;
a plurality of first connection members on the first redistribution layer structure, and around the first semiconductor die and the second semiconductor die;
a first molding material on the first redistribution layer structure, the first molding material covering the first semiconductor die and the second semiconductor die, and the first molding material at least partially surrounding the plurality of first connection members;
a second redistribution layer structure on the first molding material, the second redistribution layer structure connected to the first redistribution layer structure through the plurality of first connection members;
a third semiconductor die on the second redistribution layer structure;
a fourth semiconductor die on the second redistribution layer structure;
a dummy structure on the second redistribution layer structure, and between the third semiconductor die and the fourth semiconductor die; and
a second molding material on the second redistribution layer structure and at least partially surrounding the third semiconductor die, the fourth semiconductor die, and the dummy structure.

15. The semiconductor package of claim 14, wherein the plurality of first connection members comprise at least one conductive post.

16. The semiconductor package of claim 14, further comprising a plurality of second connection members between the second redistribution layer structure and the dummy structure,
wherein the plurality of second connection members comprise solder balls or micro bumps.

17. The semiconductor package of claim 14, wherein the dummy structure overlaps with a portion of the first semiconductor die and a portion of the second semiconductor die.

18. The semiconductor package of claim 14, wherein a portion of the dummy structure and a portion of the third semiconductor die overlap the first semiconductor die.

19. The semiconductor package of claim 14, wherein a portion of the dummy structure and a portion of the fourth semiconductor die overlap the second semiconductor die.

20. A manufacturing method of a semiconductor package comprising:
forming a first redistribution layer structure on a carrier;
forming a plurality of connection members on the first redistribution layer structure;
providing a first set of semiconductor dies on the first redistribution layer structure;
molding the plurality of connection members and the first set of semiconductor dies with a first molding material on the first redistribution layer structure;
forming a second redistribution layer structure on the first molding material;
providing a dummy structure on the second redistribution layer structure; and
providing a second set of semiconductor dies on the second redistribution layer structure,
wherein the dummy structure is provided between a first semiconductor die of the second set of semiconductor dies and a second semiconductor die of the second set of semiconductor dies.
